(19) United States
(12) Patent Application Publication
(10) Pub. No.: US 2024/0332381 A1
(43) Pub. Date: Oct. 3, 2024

(54) SEMICONDUCTOR DEVICE AND METHOD FOR FABRICATING THE SAME

(71) Applicant: Samsung Electronics Co., Ltd., Suwon-si (KR)

(72) Inventors: Ji Won KANG, Suwon-si (KR); Chung Hwan SHIN, Suwon-si (KR); Seong Heum CHOI, Suwon-si (KR); Rak Hwan KIM, Suwon-si (KR)

(21) Appl. No.: 18/382,395

(22) Filed: Oct. 20, 2023

(30) Foreign Application Priority Data
Mar. 27, 2023 (KR) 10-2023-0039908

(51) Int. Cl. H01L 29/417; H01L 29/06; H01L 29/40; H01L 29/423; H01L 29/45; H01L 29/775; H01L 29/78

(52) U.S. Cl. CPC H01L 29/41791; H01L 29/0673; H01L 29/401; H01L 29/41733; H01L 29/42392; H01L 29/45; H01L 29/775; H01L 29/7851

(57) ABSTRACT

A semiconductor device may include an active pattern extending in a first direction, a gate structure which is placed on the active pattern to be spaced apart from each other in the first direction, and includes a gate electrode and a gate spacer, the gate electrode extending in a second direction intersecting the first direction, a gate contact on the gate structure, a source/drain pattern on the active pattern, a source/drain contact on the source/drain pattern, and a via plug on the source/drain contact. An upper surface of the gate contact and a second upper surface of the via plug may be placed on the same plane. A lower surface of the gate contact and a lower surface of the via plug may be different in height, on the basis of an upper surface of the active pattern.

### CROSS-REFERENCE TO RELATED APPLICATION(S)

This application claims priority under 35 U.S.C. § 119 to Korean Patent Application No. 10-2023-0039908 filed on Mar. 27, 2023, in the Korean Intellectual Property Office, the disclosure of which in its entirety is herein incorporated by reference.

### BACKGROUND

### 1. Field of the Invention

The present invention relates to a semiconductor device and a method for fabricating the same.

### 2. Description of the Related Art

As one of scaling technologies for increasing density of a semiconductor device, a multi gate transistor in which a multi-channel active pattern (or a silicon body) having a fin or nanowire shape is formed on a substrate and a gate is formed on a surface of the multi-channel active pattern has been proposed.

On the other hand, as a pitch size of the semiconductor device becomes smaller, a research for reducing the capacitance between contacts in the semiconductor device and ensuring electrical stability is required. In addition, it may be beneficial to reduce cost of fabricating the semiconductor device by simplifying the process steps of the fabrication.

### SUMMARY

Aspects of the present invention provide a semiconductor device having improved product reliability.

Aspects of the present invention also provide a method for fabricating a semiconductor device having improved product reliability.

According to some aspects of the present inventive concept, there is provided a semiconductor device. The semiconductor device may include an active pattern extending in a first direction, a gate structure which is placed on the active pattern to be spaced apart from each other in the first direction, and includes a gate electrode and a gate spacer, the gate electrode extending in a second direction intersecting the first direction, a gate contact on the gate structure, a source/drain pattern on the active pattern, a source/drain contact on the source/drain pattern, and a via plug on the source/drain contact. An upper surface of the gate contact and an upper surface of the via plug may be placed on the same plane. A lower surface of the gate contact and a lower surface of the via plug may be different in height, on the basis of an upper surface of the active pattern.

According to some aspects of the present inventive concept, there is provided a semiconductor device. The semiconductor device may include an active pattern extending in a first direction, a gate structure which is placed on the active pattern to be spaced apart from each other in the first direction, and includes a gate electrode and a gate spacer, the gate electrode extending in a second direction perpendicular to the first direction, a gate contact on the gate structure, a source/drain pattern on the active pattern, a source/drain contact on the source/drain pattern, and a via plug on the source/drain contact. Each of the gate contact and the via plug may not include titanium, and may include tungsten of a single grain.

According to some aspects of the present inventive concept, there is provided a semiconductor device. The semiconductor device may include an active pattern extending in a first direction, a gate structure which is placed on the active pattern to be spaced apart in the first direction, and includes a gate electrode and a gate spacer, the gate electrode extending in a second direction intersecting the first direction, a gate contact on the gate structure, a source/drain pattern on the active pattern, a source/drain contact on the source/drain pattern, a via plug on the source/drain contact, and a wiring line which is in contact with the gate contact and the via plug. An upper surface of the gate contact and an upper surface of the via plug may be placed on the same plane. Each of the gate contact and the via plug may include tungsten of single grain. The gate contact may include a contact liner, and a contact filling film on the contact liner. A lower surface of the contact filling film may include a convex shape toward the gate electrode.

According to some aspects of the present inventive concept, there is provided a method for fabricating a semiconductor device. The method may include forming a source/drain pattern and a gate structure including a gate electrode, on an active pattern, forming a source/drain contact on the source/drain pattern, forming an interlayer insulating film on the gate structure and the source/drain contact, forming a gate contact hole which penetrates the interlayer insulating film and exposes the gate electrode, forming a via hole which penetrates the interlayer insulating film and exposes the source/drain contact, forming a liner which extends along profiles of the gate contact hole and the via hole, and includes tungsten, and forming a filling film which fills the gate contact hole and the via hole and includes tungsten, on the liner. The forming of the gate contact hole and the forming of the via hole may be simultaneously performed.

However, aspects of the present invention are not restricted to the one set forth herein. The above and other aspects of the present invention will become more apparent to one of ordinary skill in the art to which the present invention pertains by referencing the detailed description of the present invention given below.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary layout diagram for explaining a semiconductor device according to some embodiments.

FIG. 2 is an exemplary cross-sectional view taken along A-A of FIG. 1.

FIG. 3 is an enlarged view of a portion P of FIG. 2.

FIG. 4 is an enlarged view of a portion Q of FIG. 2.

FIG. 5 is a cross-sectional view taken along B-B of FIG. 1.

FIG. 6 is a cross-sectional view taken along C-C of FIG. 1.

FIGS. 7 and 8 are diagrams for explaining a semiconductor device according to some other embodiments.

FIG. 9 is a diagram for explaining a semiconductor device according to some other embodiments.

FIG. 10 is an enlarged view of a portion P of FIG. 9.

FIG. 11 is an enlarged view of a portion Q of FIG. 9.

FIGS. 12 and 13 are diagrams for explaining a semiconductor device according to some other embodiments.

FIGS. 14 to 18 are diagrams for explaining a semiconductor device according to some other embodiments.

FIGS. 19 to 31 are intermediate step diagrams for describing a method for fabricating a semiconductor device according to some embodiments.

### DETAILED DESCRIPTION OF THE EMBODIMENTS

Hereinafter, embodiments according to the technical idea of the present invention will be described with reference to the accompanying drawings.

Although drawings according to a semiconductor device according to some embodiments show a fin-shaped field-effect transistor (FinFET) including a channel region of a fin-shaped pattern shape, a transistor including a nanowire or a nanosheet, and a multi-bridge channel FET (MBCFET™) or a vertical transistor (Vertical FET) as an example, the embodiments are not limited thereto. The semiconductor device according to some embodiments may, of course, include a tunneling transistor (tunneling FET) or a three-dimensional (3D) transistor. The semiconductor device according to some embodiments may, of course, include a planar transistor. In addition, the technical idea of the present invention may be applied to a transistor based on two-dimensional material (2D material based FETs) and a heterostructure thereof.

Further, the semiconductor device according to some embodiments may also include a bipolar junction transistor, a laterally diffused metal oxide semiconductor (LDMOS), or the like.

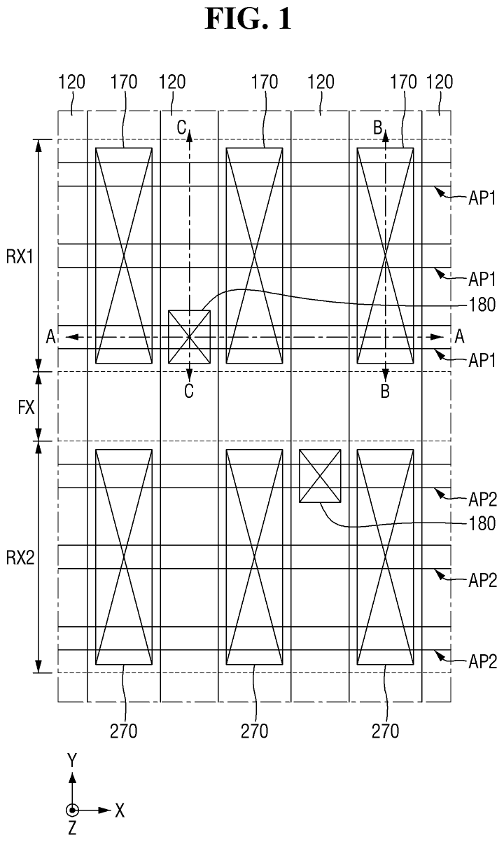

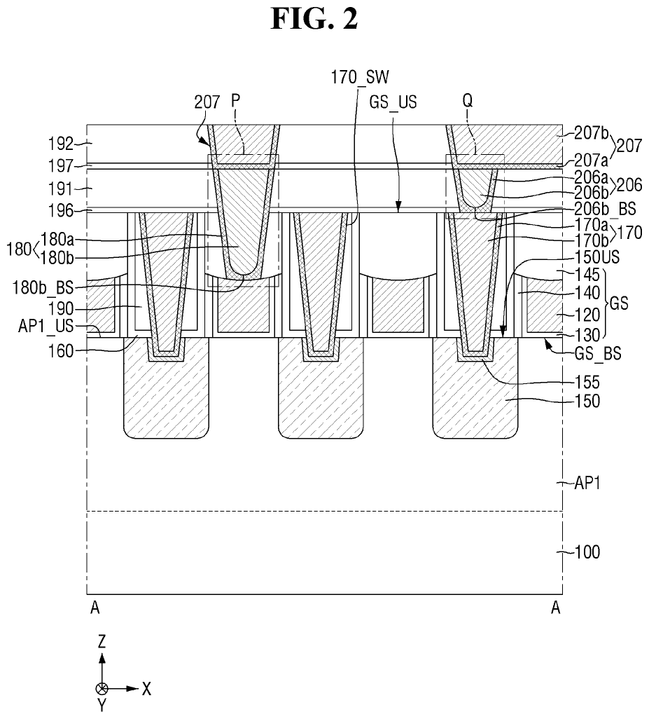

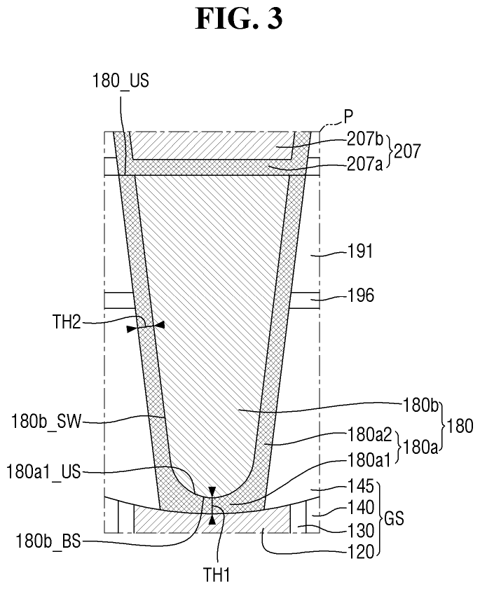

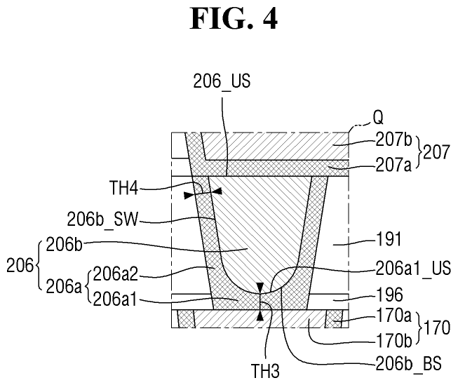

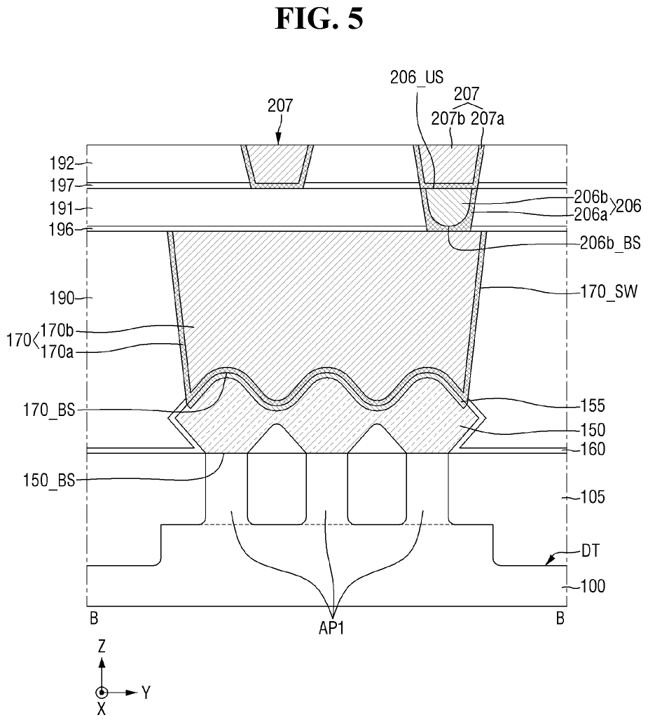

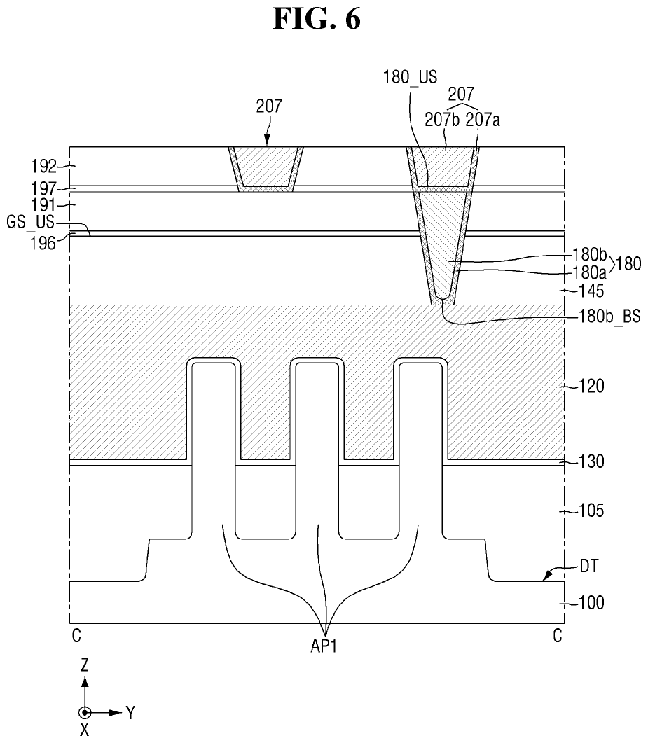

FIG. 1 is an exemplary layout diagram for explaining a semiconductor device according to some embodiments. FIG. 2 is an exemplary cross-sectional view taken along A-A of FIG. 1. FIG. 3 is an enlarged view of a portion P of FIG. 2. FIG. 4 is an enlarged view of a portion Q of FIG. 2. FIG. 5 is a cross-sectional view taken along B-B of FIG. 1. FIG. 6 is a cross-sectional view taken along C-C of FIG. 1.

Although not shown, a cross-sectional view taken along the second active pattern AP2 in a first direction X may be similar to that of FIG. 2, except positions and the like of a via plug 206 and a wiring line 207.

Referring to FIGS. 1 to 6, a semiconductor device according to some embodiments may include one or more first active patterns AP1, one or more second active patterns AP2, one or more first gate electrodes 120, a first source/drain contact 170, a second source/drain contact 270, and a gate contact 180.

The substrate 100 may include a first active region RX1, a second active region RX2, and a field region FX. The field region FX may be formed to be immediately adjacent to the first active region RX1 and the second active region RX2. The field region FX may form a boundary with the first active region RX1 and the second active region RX2.

The first active region RX1 and the second active region RX2 are spaced apart from each other. The first active region RX1 and the second active region RX2 may be separated by the field region FX.

In other words, an element isolation film may be placed around the first active region RX1 and the second active region RX2 that are spaced apart from each other. At this time, a portion of the element isolation film between the first active region RX1 and the second active region RX2 may be the field region FX. For example, a portion in which a channel region of a transistor, which may be an example of the semiconductor device, is formed may be the active region, and a portion that divides the channel region of the transistor formed in the active region may be the field region. Alternatively, the active region may be a portion in which a fin-shaped pattern or nanosheet used as a channel region of a transistor is formed, and the field region may be a region in which the fin-shaped pattern or nanosheet used as the channel region is not formed.

As shown in FIGS. 5 and 6, although the field region FX may be defined by a deep trench DT, the embodiment is not limited thereto. In addition, it is obvious that a person of ordinary skill in the technical field to which the present invention pertains may distinguish which portion is a field region and which portions is an active region.

As an example, one of the first active region RX1 and the second active region RX2 may be a PMOS formation region and the other may be an NMOS formation region. As another example, the first active region RX1 and the second active region RX2 may be the PMOS formation regions. As yet another example, the first active region RX1 and the second active region RX2 may be the NMOS formation region.

The substrate 100 may be a silicon substrate or silicon-on-insulator (SOI). In contrast, the substrate 100 may include, but is not limited to, silicon-germanium, silicon germanium on insulator (SGOI), indium antimonide, lead telluride, indium arsenide, indium phosphide, gallium arsenide or gallium antimonide.

One or more first active patterns AP1 may be formed in the first active region RX1. The first active pattern AP1 may protrude from the substrate 100 of the first active region RX1. The first active pattern AP1 may extend long along the first direction X on the substrate 100. For example, the first active pattern AP1 may include a long side extending in the first direction X, and a short side extending in a second direction Y. Here, the first direction X may intersect the second direction Y. The first direction X and the second direction Y may represent directions in parallel with an upper surface of the substrate 100, and the first direction X and the second direction Y may include directions perpendicular to each other. A third direction Z may be a thickness direction of the substrate 100. The third direction Z may represent a direction perpendicular to the upper surface of the substrate 100, and the Z-axis direction may include a direction perpendicular to an X-Y plane.

One or more second active patterns AP2 may be formed in the second active region RX2. The description for the second active pattern AP2 may be substantially the same as the description for the first active pattern AP1.

Each of the first active pattern AP1 and the second active pattern AP2 may be a multi-channel active pattern. In the semiconductor device according to some embodiments, each of the first active pattern AP1 and the second active pattern AP2 may be, for example, a fin-shaped pattern. Each of the first active pattern AP1 and the second active pattern AP2 may be used as a channel region of a transistor. Although the number of each of the first active pattern AP1 and the number of the second active patterns AP2 is shown as three, this is only for convenience of explanation, and the embodiment is not limited thereto. Each of the first active pattern AP1 and the second active pattern AP2 may be one or more.

Each of the first active pattern AP1 and the second active pattern AP2 may be a part of the substrate 100, and may include an epitaxial layer grown from the substrate 100. The first active pattern AP1 and the second active pattern AP2 may include, for example, silicon or germanium which is an elemental semiconductor material. Also, the first active pattern AP1 and the second active pattern AP2 may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

As an example, the first active pattern AP1 and the second active pattern AP2 may include the same material. For example, the first active pattern AP1 and the second active pattern AP2 may each be a silicon fin-shaped pattern. Alternatively, for example, the first active pattern AP1 and the second active pattern AP2 may each be a fin-shaped pattern including a silicon-germanium pattern. As another example, the first active pattern AP1 and the second active pattern AP2 may include different materials from each other. For example, the first active pattern AP1 may be a silicon fin-shaped pattern, and the second active pattern AP2 may be a fin-shaped pattern including a silicon-germanium pattern.

A field insulating film 105 may be formed on the substrate 100. The field insulating film 105 may be formed over the first active region RX1, the second active region RX2, and the field region FX. The field insulating film 105 may fill the deep trench DT.

The field insulating film 105 may cover side walls of the first active pattern AP1 and side walls of the second active pattern AP2. The first active pattern AP1 and the second active pattern AP2 may protrude upward from the upper surface of the field insulating film 105, respectively. The field insulating film 105 may include, for example, an oxide film, a nitride film, an oxynitride film or a combined film thereof.

One or more gate structures GS may be placed on the substrate 100. For example, one or more gate structures GS may be placed on the field insulating film 105. The gate structure GS may extend in the second direction Y. Adjacent gate structures GS may be spaced apart from each other in the first direction X.

The gate structure GS may be placed on the first active pattern AP1 and the second active pattern AP2. The gate structure GS may intersect the first active pattern AP1 and the second active pattern AP2.

Although the gate structure GS is shown to be placed over the first active region RX1 and the second active region RX2, this is only for convenience of explanation, and the embodiment is not limited thereto. That is, a part of the gate structure GS is separated into two portions by a gate isolation structure placed on the field insulating film 105, and may be placed on the first active region RX1 and the second active region RX2.

The gate structure GS may include, for example, a gate electrode 120, a gate insulating film 130, a gate spacer 140, and a gate capping film 145.

The gate electrode 120 may be placed on the first active pattern AP1 and the second active pattern AP2. The gate electrode 120 may intersect the first active pattern AP1 and the second active pattern AP2. The gate electrode 120 may wrap the first active pattern AP1 and the second active pattern AP2 that protrude beyond the upper surface of the field insulating film 105. The gate electrode 120 may include a long side extending in the second direction Y, and a short side extending in the first direction X.

The upper surface of the gate electrode 120 may be, but is not limited to, a concave curved surface that is recessed toward the upper surface of the first active pattern AP1. For example, unlike the shown example, the upper surface of the gate electrode 120 may be a flat plane.

The gate electrode 120 may include, for example, but is not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof.

The gate electrodes 120 may include conductive metal oxide, conductive metal oxynitride, and the like, and may include oxidized forms of the above materials.

The gate electrode 120 may be placed on both sides of a source/drain pattern 150, which will be described later. The gate structure GS may be placed on both sides of the source/drain pattern 150 in the first direction X.

As an example, both the gate electrodes 120 placed on both sides of the source/drain pattern 150 may be normal gate electrodes used as transistor gates. As another example, the gate electrode 120 placed on one side of the source/drain pattern 150 is used as a gate of a transistor, but the gate electrode 120 placed on the other side of the source/drain pattern 150 may be a dummy gate electrode.

The gate spacer 140 may be placed on the side walls of gate electrode 120. The gate spacer 140 may extend in the second direction Y. The gate spacer 140 may include, for example, but is not limited to, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof.

The gate insulating film 130 may extend along side walls and a bottom surface of the gate electrode 120. The gate insulating film 130 may be formed on the first active pattern AP1, the second active pattern AP2, and the field insulating film 105. The gate insulating film 130 may be formed between the gate electrode 120 and the gate spacer 140.

The gate insulating film 130 may be formed along the profile of the first active pattern AP1 protruding above the field insulating film 105, and the upper surface of the field insulating film 105. Although not shown, the first gate insulating film 130 may be formed along the profile of the second active pattern AP2 protruding above the field insulating film 105.

The gate insulating film 130 may include silicon oxide, silicon oxynitride, silicon nitride or a high dielectric constant material having a dielectric constant greater than that of silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the gate insulating film 130 is shown as a single film, this is only for convenience of explanation, and the embodiment is not limited thereto. The gate insulating film 130 may include a plurality of films. The gate insulating film 130 may include an interfacial layer placed between the first active pattern AP1 and the gate electrode 120, and between the second active pattern AP2 and the gate electrode 120, and a high dielectric constant insulating film. For example, the interfacial layer may be formed along the profile of the first active pattern AP1 and the profile of the second active pattern AP2 that protrudes above the field insulating film 105.

A semiconductor device according to some embodiments may include a negative capacitance (NC) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) under 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. A thickness of the ferroelectric material film may be, for example, but is not limited to, 0.5 to 10 nm. Since a critical thickness that exhibits the ferroelectric properties may vary for each ferroelectric material, the thickness of the ferroelectric material film may vary depending on the ferroelectric material.

As an example, the gate insulating film 130 may include a single ferroelectric material film. As another example, the gate insulating film 130 may each include a plurality of ferroelectric material films spaced apart from each other. The gate insulating film 130 may have a stacked film structure in which the plurality of ferroelectric material films and the plurality of paraelectric material films are alternately stacked.

A gate capping film 145 may be placed on the upper surface of the gate electrode 120 and the upper surface of the gate spacer 140. The upper surface of the gate capping film 145 may be an upper surface GS_US of the gate structure. The gate capping film 145 may include, for example, at least one of silicon nitride (SiN), silicon oxynitride (SiON), silicon oxide (SiO₂), silicon carbonitride (SiCN), silicon oxycarbonitride (SiOCN), and combinations thereof.

The gate capping film 145 may be placed between the gate spacers 140, unlike the shown example. In this case, the upper surface of the gate capping film 145 may be coplanar with the upper surface of the gate spacer 140. In such a case, the upper surface GS_US of the gate structure may include the upper surface of the gate capping film 145 and the upper surface of the gate spacer 140.

A source/drain pattern 150 may be located on the substrate 100. The source/drain pattern 150 may be formed on the first active pattern AP1. The source/drain pattern 150 is connected to the first active pattern AP1. A bottom surface 150_BS of the first source/drain pattern is in contact with the first active pattern AP1.

The source/drain pattern 150 may be placed on the side surfaces of the gate structure GS. The source/drain pattern 150 may be placed between the gate structures GS.

For example, the source/drain patterns 150 may be placed on both sides of the gate structure GS. Unlike the shown example, the source/drain pattern 150 may be placed on one side of the gate structure GS, and may not be placed on the other side of the gate structure GS.

The source/drain patterns 150 may include an epitaxial pattern. The source/drain patterns 150 may include a semiconductor material. The source/drain pattern 150 may be included in the source/drain of a transistor that uses the first active pattern AP1 as a channel region.

The source/drain pattern 150 may be connected to a channel region used as a channel in the first active pattern AP1. Although the source/drain pattern 150 is shown as a merged form of three epitaxial patterns formed on each first active pattern AP1, this is only for convenience of explanation, and the embodiment is not limited thereto. That is, the epitaxial patterns formed on each of the first active patterns AP1 may be separated from each other.

As an example, an air gap may be placed in a space between the source/drain patterns 150 merged with the field insulating films 105. As another example, an insulating material may be filled in the space between the source/drain patterns 150 merged with the field insulating film 105.

Although not shown, the source/drain pattern as described above may be placed on the second active pattern AP2 between the gate structures GS.

A source/drain etching stop film 160 may extend along the upper surface of the field insulating film 105, the side walls of the gate structure GS, and the profile of the source/drain pattern 150. The source/drain etching stop film 160 may be placed on the upper surface of the source/drain pattern 150 and side walls of the source/drain pattern 150.

The source/drain etching stop film 160 may include a material having an etching selectivity with respect to a first interlayer insulating film 190 to be described later. The source/drain etching stop film 160 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof.

A first interlayer insulating film 190 is placed on the source/drain etching stop film 160. The first interlayer insulating film 190 may be formed on the field insulating film 105. The first interlayer insulating film 190 may be placed on the source/drain pattern 150. The first interlayer insulating film 190 may be placed between the source/drain etching stop film 160 and the source/drain contact barrier film 170a.

The first interlayer insulating film 190 may not cover the upper surface GS_US of the gate structure. For example, the upper surface of the first interlayer insulating film 190 may be coplanar with the upper surface GS_US of the gate structure.

The first interlayer insulating film 190 may include, but is not limited to, for example, at least one of silicon oxide, silicon nitride, silicon oxynitride, and a low dielectric constant material. The low dielectric constant material may include, for example, but is not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), Poly TetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica or combinations thereof.

A first source/drain contact 170 may be placed on the first active region RX1. A second source/drain contact 270 may be placed on the second active region RX2. The first source/drain contact 170 may be connected to the source/drain pattern 150 formed in the first active region RX1. Although not shown, the second source/drain contact 270 may be connected to a source/drain pattern formed in the second active region RX2.

A part of the first source/drain contact 170 may be directly connected to a part of the second source/drain contact 270, unlike the shown example. For example, in the semiconductor device according to some embodiments, at least one or more source/drain contacts may be placed over the first active region RX1 and the second active region RX2. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

Since the matters of the second source/drain contact 270 are substantially the same as those of the first source/drain contact 170, the following description will be explained, using the first source/drain contact 170 on the first active pattern AP1. Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

A gate contact 180 may be placed in the gate structure GS. The gate contact 180 may be connected to the gate electrode 120 included in the gate structure GS.

The gate contact 180 may be placed at a position that overlaps the gate structure GS. In the semiconductor device according to some embodiments, at least a part of the gate contact 180 may be placed at a position that overlaps at least one of the first active region RX1 and the second active region RX2. For example, from a planar point of view, the gate contact 180 may be placed at a position that overlaps the first active region RX1 or the second active region RX2 as a whole.

The first source/drain contact 170 may pass through the source/drain etching stop film 160 and be connected to the source/drain pattern 150. The first source/drain contact 170 may be placed on the source/drain pattern 150.

The first source/drain contact 170 may be placed in the first interlayer insulating film 190. The first source/drain contacts 170 may be surrounded by the first interlayer insulating film 190.

A contact silicide film 155 may be placed between the first source/drain contact 170 and the source/drain pattern 150. Although the contact silicide film 155 is shown as being formed along the profile of the interface between the source/drain pattern 150 and the first source/drain contact 170, the embodiment is not limited thereto. The contact silicide film 155 may include, for example, a metal silicide material.

The first interlayer insulating film 190 does not cover the upper surface of the first source/drain contact 170. As an example, the upper surface of the first source/drain contact 170 may not protrude above the upper surface GS_US of the gate structure. The upper surface of the first source/drain contact 170 may be coplanar with the upper surface GS_US of the gate structure. Unlike the shown example, as another example, the upper surface of the first source/drain contact 170 may protrude above the upper surface GS_US of the gate structure.

The first source/drain contact 170 may include a source/drain contact barrier film 170a, and a source/drain contact filling film 170b on the source/drain contact barrier film 170a. The first source/drain contact 170 may include a bottom surface 170_BS and side walls 170_SW. The source/drain contact barrier film 170a may extend along the side walls and bottom surface of the source/drain contact filling film 170b.

The bottom surface 170_BS of the source/drain contact may have a wavy shape, but is not limited thereto. For example, the bottom surface 170_BS of the source/drain contact may have a flat shape. The bottom surface 170_BS of the source/drain contact may be in contact with the contact silicide film 155.

Although the upper surface of the source/drain contact barrier film 170a is shown to be located substantially at the same height as the upper surface of the source/drain contact filling film 170b on the basis of the upper surface AP1_US of the first active pattern, the embodiment is not limited thereto.

Unlike the shown example, the upper surface of the source/drain contact barrier film 170a may be lower than the upper surface of the source/drain contact filling film 170b on the basis of the upper surface AP1_US of the first active pattern.

The source/drain contact barrier film 170a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and two-dimensional (2D) material. In the semiconductor device according to some embodiments, the two-dimensional material may be a metallic material and/or a semiconductor material. The 2D material may include a 2D allotrope or a 2D compound, and may include, but is not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed by way of example, the 2D materials that may be included in the semiconductor device of the present invention are not limited by the above-mentioned materials.

The source/drain contact filling film 170b may include, for example, at least one of aluminum (Al), tungsten (W), cobalt (Co), ruthenium (Ru), silver (Ag), gold (Au), manganese (Mn), and molybdenum (Mo).

Although the first source/drain contact 170 is shown to include a plurality of conductive films, the embodiment is not limited thereto. For example, the first source/drain contact 170 may be a single film, unlike the shown example.

A first etching stop film 196 may be placed on the first interlayer insulating film 190, the gate structure GS, and the source/drain contact 170. A second interlayer insulating film 191 may be placed on the first etching stop film 196.

The first etching stop film 196 may include a material having an etch selectivity with respect to the second interlayer insulating film 191. The first etching stop film 196 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), aluminum oxide (AlO), aluminum nitride (AlN), aluminum oxycarbide (AlOC), and combinations thereof. Although the first etching stop film 196 is shown as a single film, the embodiment is not limited thereto. Unlike the shown example, the first etching stop film 196 may not be formed. The second interlayer insulating film 191 may include, for example, at least one of silicon oxide, silicon nitride, silicon carbonitride, silicon oxynitride, and a low dielectric constant material.

The second etching stop film 197 may be placed between the second interlayer insulating film 191 and the third interlayer insulating film 192. The second etching stop film 197 may extend along the upper surface of the second interlayer insulating film 191.

The second etching stop film 197 may include a material having an etch selectivity with respect to the third interlayer insulating film 192. Contents of the materials included in the second etching stop film 197 may be the same as those of the first etching stop film 196. Although the second etching stop film 197 is shown as a single film, the embodiment is not limited thereto. Unlike the shown example, the second etching stop film 197 may not be formed. The third interlayer insulating film 192 may include, for example, at least one of silicon oxide, silicon nitride, silicon carbonitride, silicon oxynitride, and a low dielectric constant material.

A gate contact 180 may be placed on the gate electrode 120. The gate contact 180 may pass through the gate capping film 145, and be connected to the gate electrode 120. The gate contact 180 may pass through the first etching stop film 196 and the second interlayer insulating film 191.

As an example, the upper surface of the gate contact 180 may protrude above the upper surface GS_US of the gate structure. As another example, the upper surface of the gate contact 180 may be coplanar with the upper surface GS_US of the gate structure, unlike the shown example.

The gate contact 180 may include a gate contact liner 180a, and a gate contact filling film 180b on the gate contact liner 180a. The gate contact liner 180a may extend along a side wall portion 180b_SW of the gate contact filling film and a bottom surface 180b_BS of the gate contact filling film.

The gate contact liner 180a may include a first bottom portion 180a1 and a first side wall portion 180a2. The first bottom portion 180a1 may be placed under the gate contact filling film 180b. The first bottom portion 180a1 may be placed under the bottom surface 180b_BS of the gate contact filling film. The first bottom portion 180a1 may wrap the bottom surface 180b_BS of the gate contact filling film.

The first side wall portion 180a2 may be placed on a side portion of the gate contact filling film 180b. The first side wall portion 180a2 may be placed on the side wall portion 180b_SW of the gate contact filling film. The first side wall portion 180a2 may extend along the side wall portion 180b_SW of the gate contact filling film. The first side wall portion 180a2 may extend from the first bottom portion 180a1. Specifically, the first side wall portion 180a2 may extend from the first bottom portion 180a1 in the direction away from the gate electrode 120.

The gate contact liner 180a and the gate contact filling film 180b may have a U-shape. Specifically, the upper surface 180a1_US of the first bottom portion of the gate contact liner 180a may have a convex shape toward the gate electrode 120. A bottom surface 180b_BS of the gate contact filling film may have a convex shape toward the gate electrode 120.

A first thickness TH1 of the first bottom portion 180a1 of the gate contact liner 180a may be the same as a second thickness TH2 of the first side wall portion 180a2 of the gate contact liner 180a. For example, the first thickness TH1 of the first bottom portion 180a1 may refer to the shortest distance between the upper surface 180a1_US of the first bottom portion and the upper surface of the gate electrode 120. The second thickness TH2 of the first side wall portion 180a2 may refer to a distance between the side wall portion 180b_SW of the gate contact filling film and the outer wall of the first side wall portion 180a2.

Although FIG. 3 shows that the first thickness TH1 of the first bottom portion 180a1 is the same as the second thickness TH2 of the first side wall portion 180a2, the embodiment is not limited thereto. For example, the first thickness TH1 of the first bottom portion 180a1 may be smaller than the second thickness TH2 of the first side wall portion 180a2.

The upper surface 180_US of the gate contact may be covered with the wiring line 207. The upper surface 180_US of the gate contact may be coplanar with the lower surface of the wiring line 207. The upper surface 180_US of the gate contact may be coplanar with the upper surface of the second interlayer insulating film 191. The upper surface 180_US of the gate contact may be coplanar with an upper surface 206_US of the via plug.

The gate contact liner 180a and the gate contact filling film 180b may include the same material. For example, both the gate contact liner 180a and the gate contact filling film 180b may include tungsten (W).

The gate contact 180 may include or be formed of a single grain. For example, the gate contact liner 180a and the gate contact filling film 180b may include or be formed of tungsten of the single grain. The gate contact liner 180a and the gate contact filling film 180b may not include a plurality of grains divided by a grain boundary.

The gate contact liner 180a and the gate contact filling film 180b may not contain titanium (Ti). The gate contact liner 180a and the gate contact filling film 180b may not contain titanium nitride (TiN). The gate contact liner 180a and the gate contact filling film 180b may not contain silane (SiH₄). The gate contact liner 180a and the gate contact filling film 180b may not contain Si—H bonds. The gate contact liner 180a and the gate contact filling film 180b may not contain boron (B).

In the wiring line 207 and the gate contact 180, the gate contact 180 may not include a barrier film, unlike the first source/drain contact 170.

The via plug 206 may be placed in the second interlayer insulating film 191. The via plug 206 passes through the first etching stop film 196, and may be connected to the first source/drain contact 170. The via plug 206 may not be placed on the gate contact 180.

The via plug 206 may include a via liner 206a and a via filling film 206b. The via liner 206a may extend along a side wall portion 206b_SW and a bottom surface 206b BS of the via filling film.

The via liner 206a may include a second bottom portion 206a1 and a second side wall portion 206a2. The second bottom portion 206a1 may be placed below the via filling film 206b. The second bottom portion 206a1 may be placed below the bottom surface 206b_BS of the via filling film. The second bottom portion 206a1 may wrap the bottom surface 206b_BS of the via filling film.

The second side wall portion 206a2 may be placed on the side portion of the via filling film 206b. The second side wall portion 206a2 may be placed on the side wall portion 206b_SW of the via filling film. The second side wall portion 206a2 may extend along the side wall portion 206b SW of the via filling film. The second side wall portion 206a2 may extend from the second bottom portion 206a1. Specifically, the second side wall portion 206a2 may extend from the second bottom portion 206a1 in the direction away from the first source/drain contact 170.

The via liner 206a and the via filling film 206b may have a U-shape. Specifically, the upper surface 206a1_US of the second bottom portion of the via liner 206a may have a convex shape toward the first source/drain contact 170. The bottom surface 206b_BS of the via filling film may have a convex shape toward the first source/drain contact 170.

A third thickness TH3 of the second bottom portion 206a1 of the via liner 206a may be the same as a fourth thickness TH4 of the second side wall portion 206a2 of the via liner 206a. For example, the third thickness TH3 of the second bottom portion 206a1 may refer to the shortest distance between the upper surface 206a1_US of the second bottom portion and the upper surface of the first source/drain contact 170. The fourth thickness TH4 of the second side wall portion 206a2 may refer to a distance between the side wall portion 206b_SW of the via filling film and the outer wall of the second side wall portion 206a2.

Although FIG. 4 shows that the third thickness TH3 of the second bottom portion 206a1 is the same as the fourth thickness TH4 of the second side wall portion 206a2, the embodiment is not limited thereto. For example, the third thickness TH3 of the second bottom portion 206a1 may be smaller than the fourth thickness TH4 of the second side wall portion 206a2.

The upper surface 206_US of the via plug may be covered with the wiring line 207. The upper surface 206_US of the via plug may be coplanar with the lower surface of the wiring line 207. The upper surface 206_US of the via plug may be coplanar with the upper surface of the second interlayer insulating film 191. The upper surface 206_US of the via plug may be coplanar with the upper surface 180_US of the gate contact.

The via liner 206a and the via filling film 206b may include the same material. For example, both the via liner 206a and the via filling film 206b may include tungsten (W).

The via plug 206 may include or be formed of a single grain. For example, the via liner 206a and the via filling film 206b may include or be formed of tungsten of the single grain. The via liner 206a and the via filling film 206b may not include a plurality of grains divided by a grain boundary.

The via liner 206a and the via filling film 206b may not include titanium (Ti). The via liner 206a and the via filling film 206b may not contain titanium nitride (TiN). The via liner 206a and the via filling film 206b may not contain silane (SiH₄). The via liner 206a and the via filling film 206b may not contain Si—H bonds. The gate contact liner 180a and the gate contact filling film 180b may not contain boron (B).

In the wiring line 207 and the gate contact 180, the via plug 206 may not include a barrier film, unlike the first source/drain contact 170.

The wiring line 207 may be placed in the third interlayer insulating film 192. The wiring line 207 is connected to the via plug 206. The wiring line 207 may be in contact with the via plug 206. The wiring line 207 may be in contact with the gate contact 180. The lower surface of the wiring line 207 may be coplanar with the upper surface of the gate contact 180 and the upper surface of the via plug 206.

The wiring line 207 may include a wiring barrier film 207a and a wiring filling film 207b. The wiring barrier film 207a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and two-dimensional (2D) material. The wiring filling film 207b may each include, for example, at least one of aluminum (Al), copper (Cu), tungsten (W), cobalt (Co), ruthenium (Ru), silver (Ag), gold (Au), manganese (Mn), and molybdenum (Mo).

Unlike the shown example, the wiring barrier film 207a may not be placed between the via filling film 206b and the wiring filling film 207b. Further, unlike the shown example, the wiring barrier film 207a may not be placed between the gate contact filling film 180b and the wiring filling film 207b.

The gate contact 180 and the via plug 206 may be formed at the same level. The “same level” means formation by the same fabricating process. For example, the gate contact 180 and the via plug 206 may be formed simultaneously through etching and vapor deposition processes.

The gate contact 180 and the via plug 206 may have different aspect ratios. For example, the upper surface 180_US of the gate contact and the upper surface 206_US of the via plug are placed on the same plane, and meanwhile, the lower surface of the gate contact 180 and the lower surface of the via plug 206 may be placed on different planes. By simultaneously forming the gate contact 180 and the via plug 206 with different aspect ratios, the fabricating process may be simplified. Additionally, resistance of the gate contact 180 and the via plug 206 including a single grain may decrease.

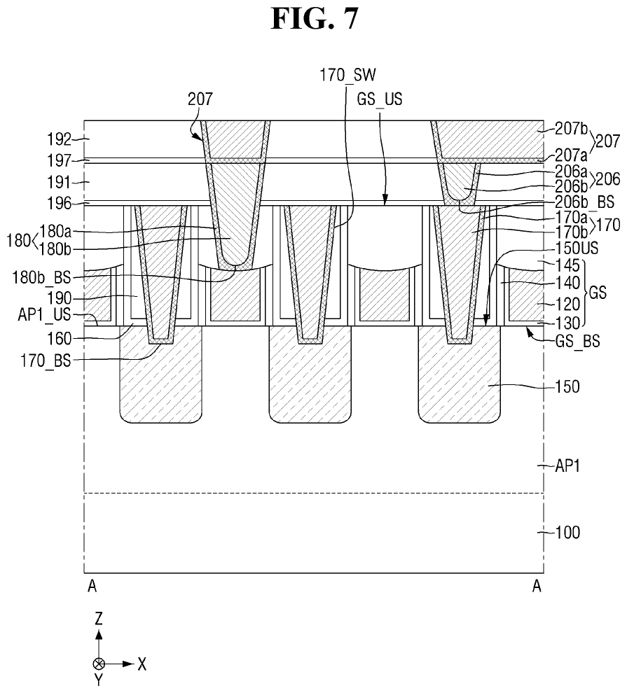

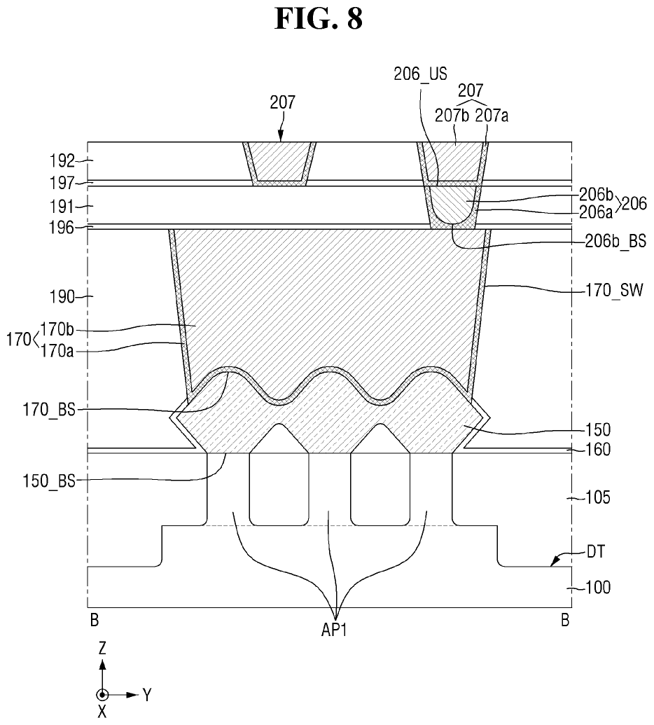

FIGS. 7 and 8 are diagrams for explaining a semiconductor device according to some other embodiments. For convenience of explanation, points different from those explained with reference to FIGS. 1 to 6 will be mainly explained.

Referring to FIGS. 7 and 8, the semiconductor device according to some embodiments may not include a contact silicide film (155 of FIG. 2). The first source/drain contact 170 may be in contact with the source/drain pattern 150. A bottom surface 170_BS of the source/drain contact may be in contact with the source/drain pattern 150.

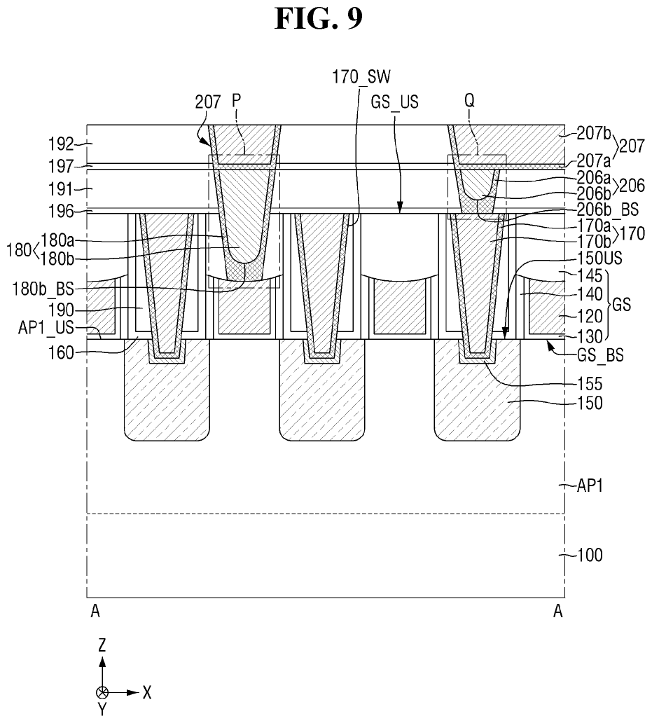

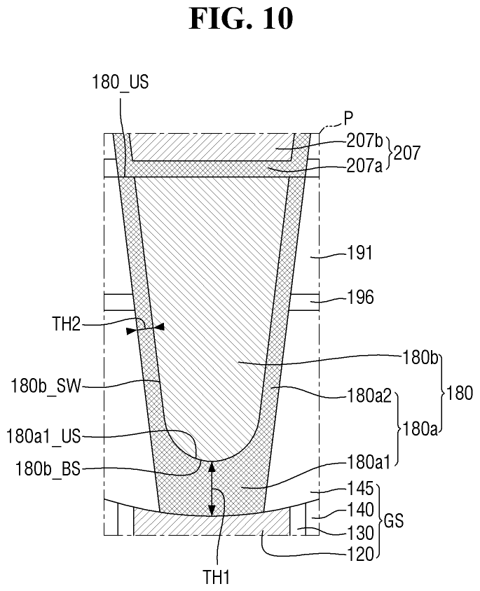

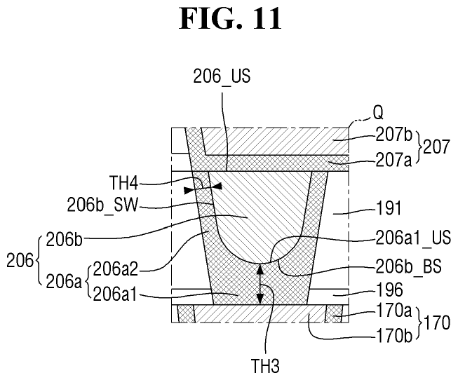

FIG. 9 is a diagram for explaining a semiconductor device according to some other embodiments. FIG. 10 is an enlarged view of a portion P of FIG. 9. FIG. 11 is an enlarged view of a portion Q of FIG. 9. For convenience of explanation, points different from those explained with reference to FIGS. 1 to 6 will be mainly explained.

Referring to FIGS. 9 to 11, the first thickness TH1 of the first bottom portion 180a1 of the gate contact liner 180a may be greater than the second thickness TH2 of the first side wall portion 180a2 of the gate contact liner 180a. Even in this case, the gate contact liner 180a and the gate contact filling film 180b may have a U-shape. The upper surface 180a1_US of the first bottom portion of the gate contact liner 180a may have a convex shape toward the gate electrode 120. The bottom surface 180b_BS of the gate contact filling film may have a convex shape toward the gate electrode 120.

The third thickness TH3 of the second bottom portion 206a1 of the via liner 206a may be greater than the fourth thickness TH4 of the second side wall portion 206a2 of the via liner 206a. Similarly, the via liner 206a and the via filling film 206b may have a U-shape. An upper surface 206a1_US of the second bottom portion of the via liner 206a may have a convex shape toward the first source/drain contact 170. A bottom surface 206b_BS of the via filling film may have a convex shape toward the first source/drain contact 170.

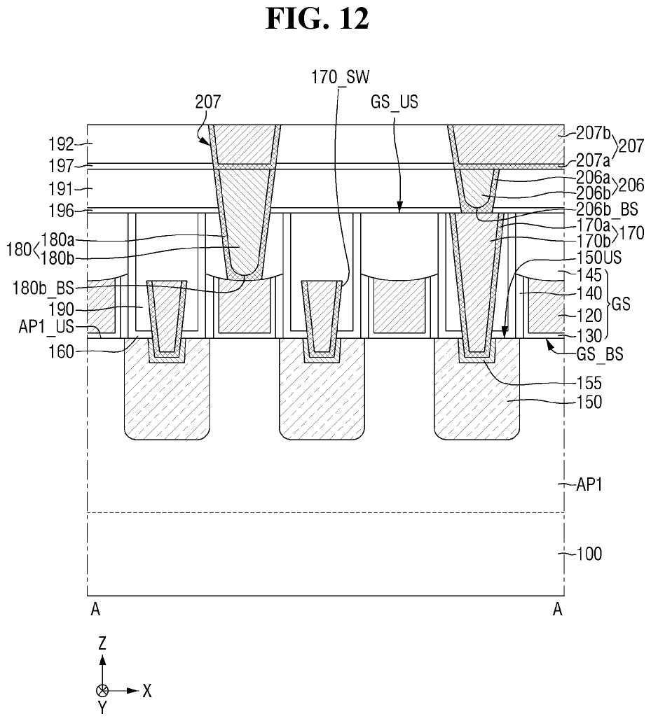

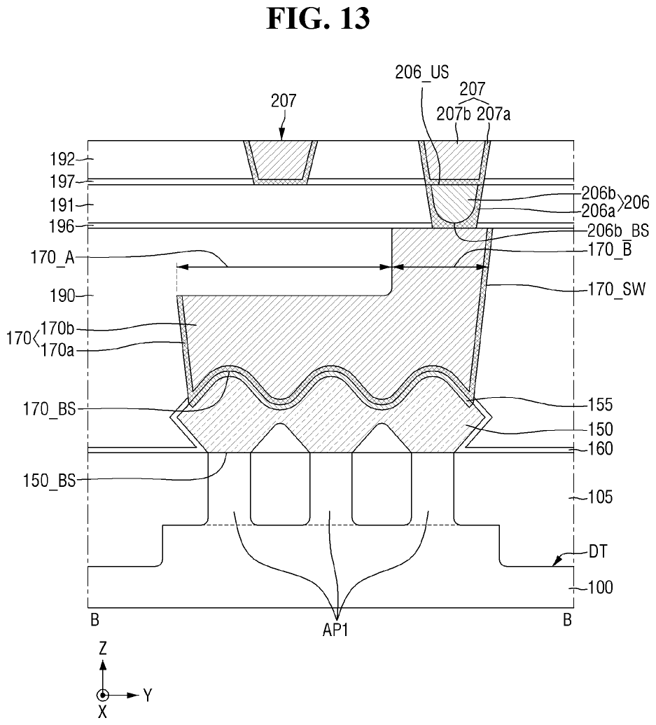

FIGS. 12 and 13 are diagrams for explaining a semiconductor device according to some other embodiments. For convenience of explanation, points different from those explained with reference to FIGS. 1 to 6 will be mainly explained.

The first source/drain contact 170 may include a first portion 170_A and a second portion 170_B.

The first portion 170_A of the first source/drain contact may be directly connected to the second portion 170_B of the first source/drain contact.

The second portion 170_B of the first source/drain contact is a portion on which the via plug 206 lands. The first source/drain contact 170 may be connected to the wiring line 207 through the second portion 170_B of the first source/drain contact. The first portion 170_A of the first source/drain contact is not a portion on which the via plug 206 lands.

For example, in the cross-sectional view of FIG. 12, the second portion 170_B of the first source/drain contact may be located at the portion connected to the via plug 206. The first portion 170_A of the first source/drain contact may be located at a portion that is not connected to the via plug 206.

In addition, in order to prevent the gate contact 180 and the first source/drain contact 170 from being short-circuited, on both sides of the gate structure GS of the portion connected to the gate contact 180, the portion 170_A of the first source/drain contact may be located, and the second portion 170_B of the first source/drain contact may not be located. For example, in a cross-sectional view such as FIG. 12, on both sides of the gate structure GS connected to the gate contact 180, the first portion 170_A of the first source/drain contact may be located, and the second portion 170_B of the first source/drain contact may not be located.

The upper surface of the second portion 170_B of the first source/drain contact may be higher than the first portion 170_A of the first source/drain contact. In FIG. 13, on the basis of the upper surface of the field insulating film 105, the upper surface of the second portion 170_B of the first source/drain contact may be higher than the first portion 170_A of the first source/drain contact. For example, the upper surface of the first source/drain contact 170 may be the upper surface of the second portion 170_B of the first source/drain contact.

In FIG. 13, the first source/drain contact 170 is shown to have an L-shape, but the embodiment is not limited thereto. Unlike the shown example, the first source/drain contacts 170 may have a T-shape that is rotated by 180 degrees. In such a case, the first portion 170_A of the first source/drain contact may be placed on both sides of the second portion 170_B of the first source/drain contact.

The first interlayer insulating film 190 may not cover the upper surface of the second portion 170_B of the first source/drain contact. The first interlayer insulating film 190 may cover the upper surface of the first portion 170_A of the first source/drain contact.

In FIG. 13, the first interlayer insulating film 190 may include a first portion and a second portion. The first portion of the first interlayer insulating film 190 may be a portion of the first interlayer insulating film 190 that overlaps the upper surface of the first portion 170_A of the first source/drain contact in the third direction Z. The second portion of the first interlayer insulating film 190 may be a remaining portion except the first portion of the first interlayer insulating film 190.

The first portion of the first interlayer insulating film 190 and the second portion of the first interlayer insulating film 190 are formed in the fabricating processes different from each other. The first source/drain contact 170 shown in FIG. 13 may be formed by removing a part of the first source/drain contact 170 shown in FIG. 5. For example, the first portion 170_A of the first source/drain contact shown in FIG. 13 may be formed by removing a part of the first source/drain contact 170 shown in FIG. 5. A second portion of the first interlayer insulating film 190 may be formed, by filling a space above the upper surface of the first portion 170_A of the first source/drain contact with an insulating material.

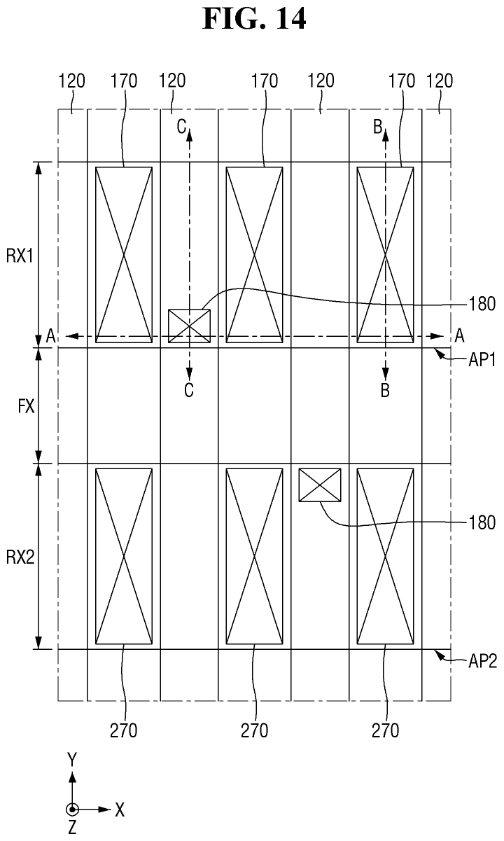

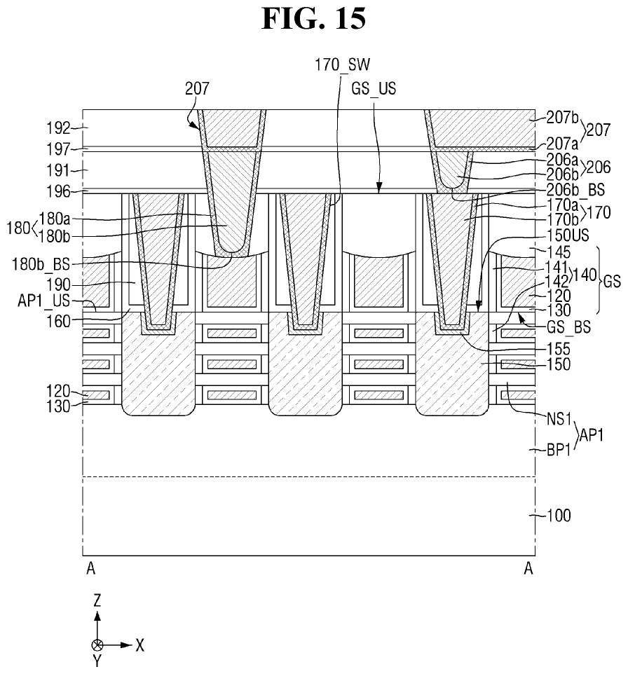

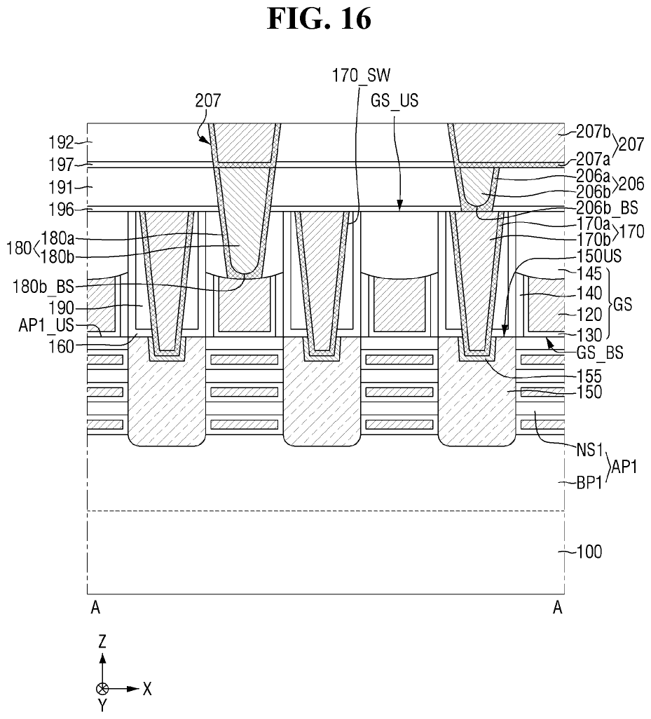

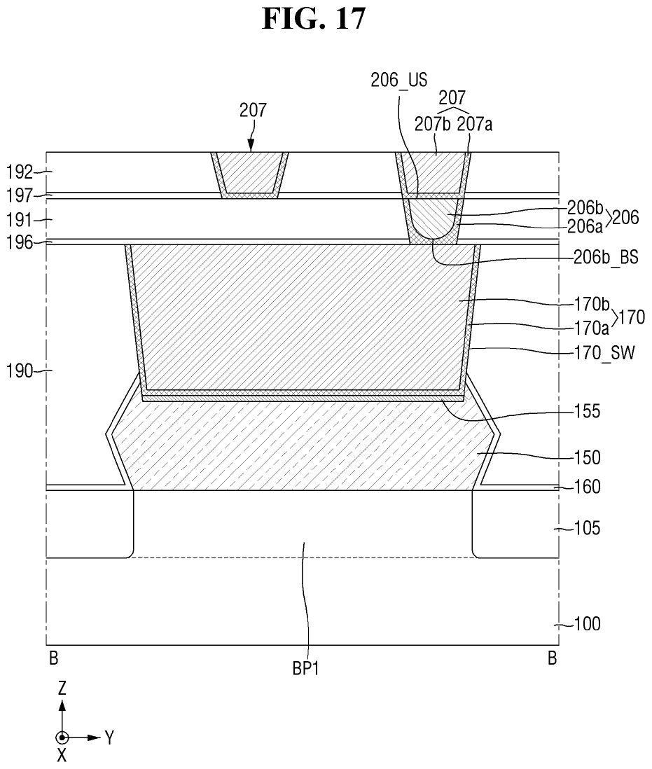

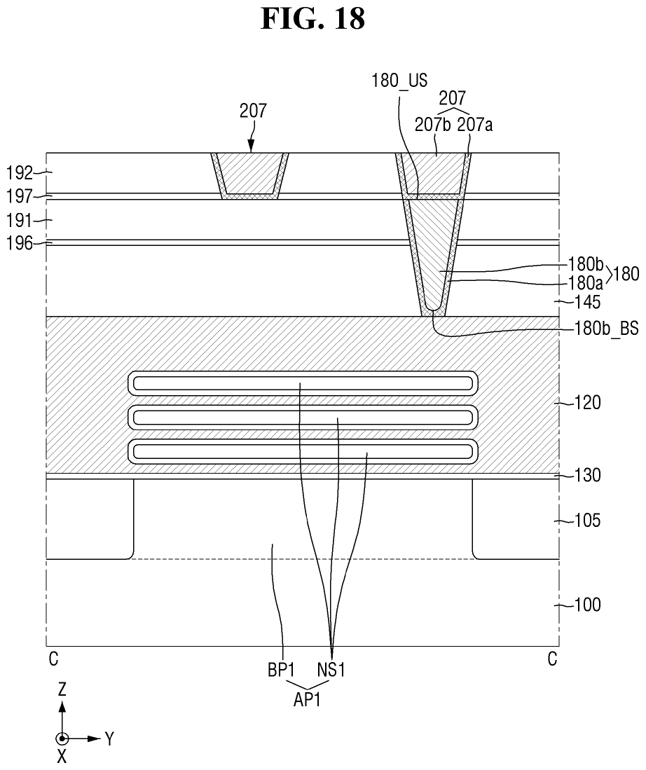

FIGS. 14 to 18 are diagrams for explaining a semiconductor device according to some other embodiments. FIG. 14 is an exemplary layout diagram for explaining a semiconductor device according to some embodiments. FIGS. 15 and 16 are exemplary cross-sectional views taken along A-A of FIG. 14, respectively. FIG. 17 is a cross-sectional view taken along B-B of FIG. 14. FIG. 18 is a cross-sectional view taken along C-C of FIG. 14. For convenience of explanation, points different from those explained referring to FIGS. 1 to 6 will be mainly explained.

Referring to FIGS. 14 to 18, in the semiconductor device according to some embodiments, a first active pattern AP1 may include a lower pattern BP1 and a sheet pattern NS1.

Although not shown, the second active pattern AP2 may include a lower pattern and a sheet pattern.

The lower pattern BP1 may extend along the first direction X. The sheet pattern NS1 may be placed on the lower pattern BP1 to be spaced apart from the lower pattern BP1.

The sheet pattern NS1 may include a plurality of sheet patterns stacked in the third direction Z. Although the three sheet patterns NS1 are shown, this is only for convenience of explanation, and the embodiment is not limited thereto. The upper surface of the sheet pattern NS1 placed on the uppermost part of the sheet pattern NS1 may be the upper surface AP1_US of the first active pattern.

The sheet pattern NS1 may be connected to the first source/drain pattern 150. The sheet pattern NS1 may be a channel pattern used as a channel region of a transistor. For example, the sheet pattern NS1 may be nanosheet or nanowire.

The lower pattern BP1 may include, for example, silicon or germanium which is the elemental semiconductor material. Alternatively, the lower pattern BP1 may include a compound semiconductor, and may include, for example, an IV-IV compound semiconductor or a group III-V compound semiconductor.

The sheet pattern NS1 may include, for example, silicon or germanium which is the elemental semiconductor material. Alternatively, the sheet pattern NS1 may include a compound semiconductor, and may include, for example, a group IV-IV compound semiconductor or a group III-V compound semiconductor.

The gate insulating film 130 may extend along the upper surface of the lower pattern BP1 and the upper surface of the field insulating film 105. The gate insulating film 130 may wrap the periphery of the sheet pattern NS1.

The gate electrode 120 is placed on the lower pattern BP1. The gate electrode 120 intersects the lower pattern BP1. The gate electrode 120 may wrap the periphery of the sheet pattern NS1. The gate electrode 120 may be placed between the lower pattern BP1 and the sheet pattern NS1, and between the adjacent sheet pattern NS1.

In FIG. 15, the gate spacer 140 may include an outer spacer 141 and an inner spacer 142. The inner spacer 142 may be placed between the lower pattern BP1 and the sheet pattern NS1, and between the adjacent sheet patterns NS1.

In FIG. 16, the gate spacer 140 may include only the outer spacer (141 of FIG. 15). No inner spacer is placed between the lower pattern BP1 and the sheet pattern NS1, and between the adjacent sheet patterns NS1.

A bottom surface of the first source/drain contact 170 may be located between the upper surface of the sheet pattern NS1 placed at the lowermost part of the plurality of sheet patterns NS1 and the lower surface of the sheet pattern NS1 placed at the uppermost part of the plurality of sheet patterns NS1. Unlike the shown example, the bottom surface of the first source/drain contact 170 may be located between the upper surface of the sheet pattern NS1 placed at the uppermost part of the plurality of sheet patterns NS1 and the lower surface of the sheet pattern NS1 placed at the uppermost part of the plurality of sheet patterns NS1.

A description of the gate contact 180 and the via plug 206 is substantially the same as the contents explained referring to FIGS. 1 to 6, and therefore, will be omitted.

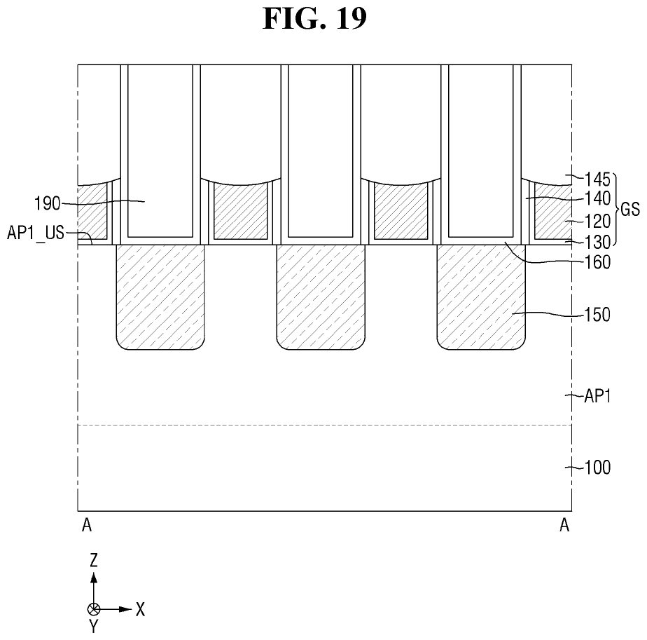

FIGS. 19 to 31 are intermediate step diagrams for describing a method for fabricating the semiconductor device according to some embodiments. For reference, FIGS. 19 to 31 are cross-sectional views taken along A-A of FIG. 1. The following fabricating method will be described in terms of cross-sectional view.

Referring to FIG. 19, the source/drain pattern 150 may be formed on the first active pattern AP1.

The source/drain etching stop film 160 and the first interlayer insulating film 190 are sequentially formed on the source/drain pattern 150.

After forming the first interlayer insulating film 190, a gate structure GS may be formed through a replacement metal gate (RMG) process.

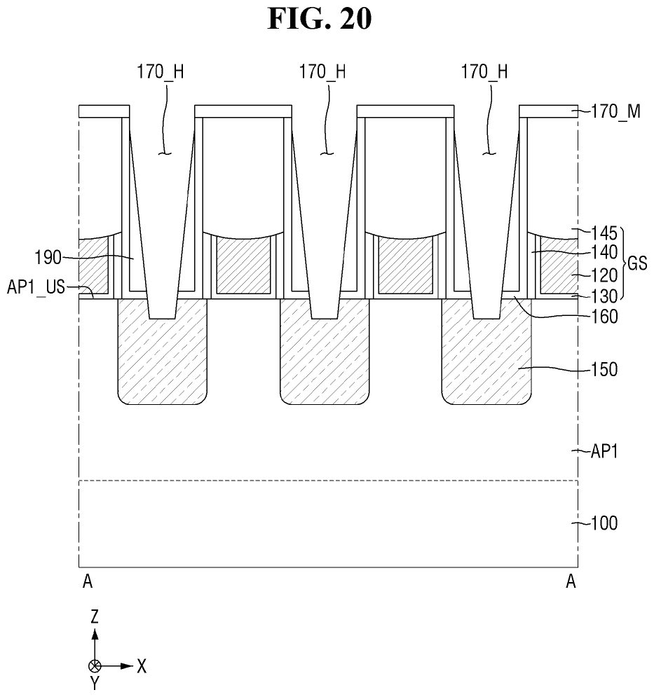

Referring to FIG. 20, a source/drain contact hole 170_H may be formed in the first interlayer insulating film 190.

Specifically, a mask buffer film may be formed on the gate structure GS. The mask buffer film may extend along the upper surface of the gate structure GS and the upper surface of the first interlayer insulating film 190. A mask pattern may be formed on the mask buffer film. The mask pattern may include a pattern for forming a source/drain contact hole 170_H. The mask buffer film may include, for example, but is not limited to, oxide.

The source/drain contact hole 170_H may be formed in the first interlayer insulating film 190, using the mask pattern as a mask. A mask buffer film may be patterned in the process of forming the source/drain contact hole 170_H. A mask buffer pattern 170_M may be formed on the gate structure GS by patterning the mask buffer film.

The source/drain contact hole 170_H may expose the source/drain etching stop film 160 and the source/drain pattern 150. The source/drain contact hole 170_H may penetrate the source/drain etching stop film 160. A part of the source/drain etching stop film 160 may be removed, while the source/drain contact hole 170_H is being formed. A part of the source/drain pattern 150 may be removed, while the source/drain contact hole 170_H is being formed.

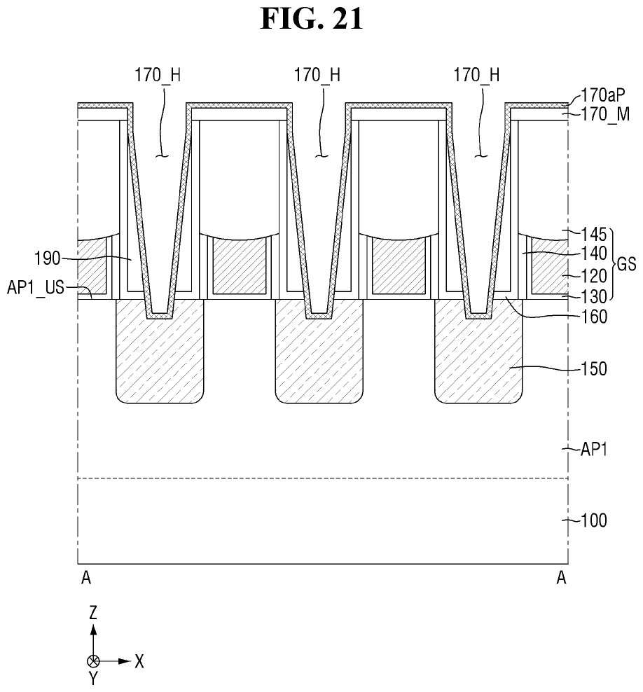

Referring to FIG. 21, a pre-source/drain contact barrier film 170aP may be formed along side walls and a bottom surface of the source/drain contact hole 170_H.

The pre-source/drain contact barrier film 170aP may be formed along the upper surface of the mask buffer pattern 170_M. The pre-source/drain contact barrier film 170aP may be formed using, for example, a chemical vapor deposition (CVD) method.

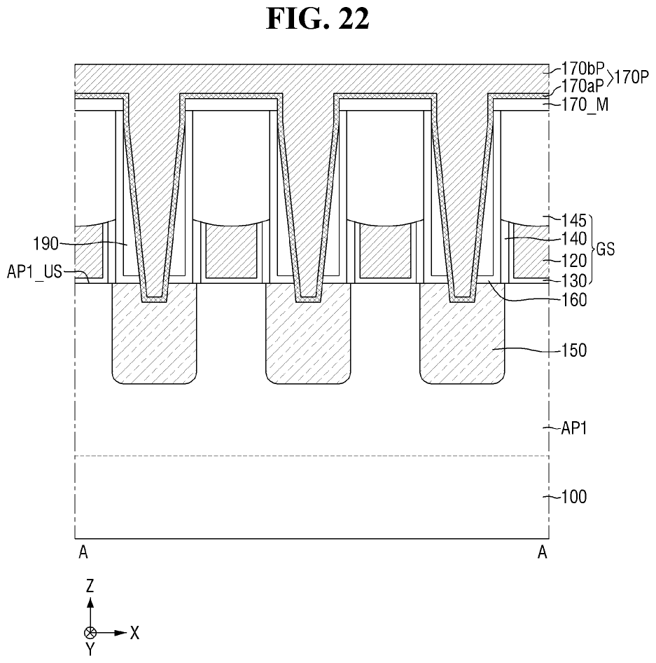

Referring to FIG. 22, a pre-source/drain contact filling film 170bP may be formed.

The pre-source/drain contact filling film 170bP may be formed on the pre-source/drain contact barrier film 170aP. The pre-source/drain contact filling film 170bP may fill the source/drain contact hole 170_H. The pre-source/drain contact filling film 170bP may fill the source/drain contact hole 170_H on the pre-source/drain contact barrier film 170aP.

As an example, the contact silicide film 155 may be formed on the source/drain pattern 150 before the pre-source/drain contact barrier film 170aP is formed. As another example, the contact silicide film 155 may be formed on the source/drain pattern 150 through a heat treatment process, while forming the pre-source/drain contact barrier film 170aP. As another example, after the pre-source/drain contact filling film 170bP is formed, the contact silicide film 155 may be formed on the source/drain pattern 150 through a heat treatment process.

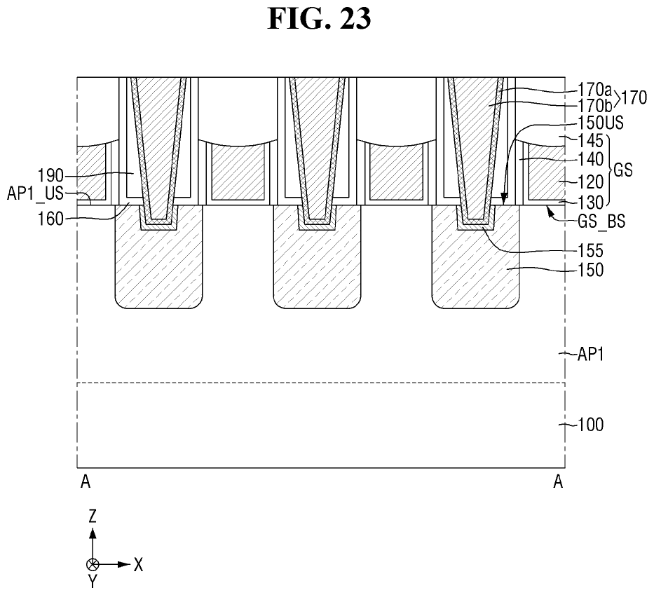

Referring to FIG. 23, a first source/drain contact 170 may be formed.

The first source/drain contact 170 is formed on the source/drain pattern 150. The first source/drain contact 170 is connected to the source/drain pattern 150.

More specifically, a part of the pre-source/drain contact barrier film 170aP and a part of the pre-source/drain contact filling film 170bP may be removed to form the first source/drain contact 170. The mask buffer pattern 170_M may be removed, while the first source/drain contact 170 is being formed. A part of the gate capping film 145 may also be removed, while the first source/drain contact 170 is being formed.

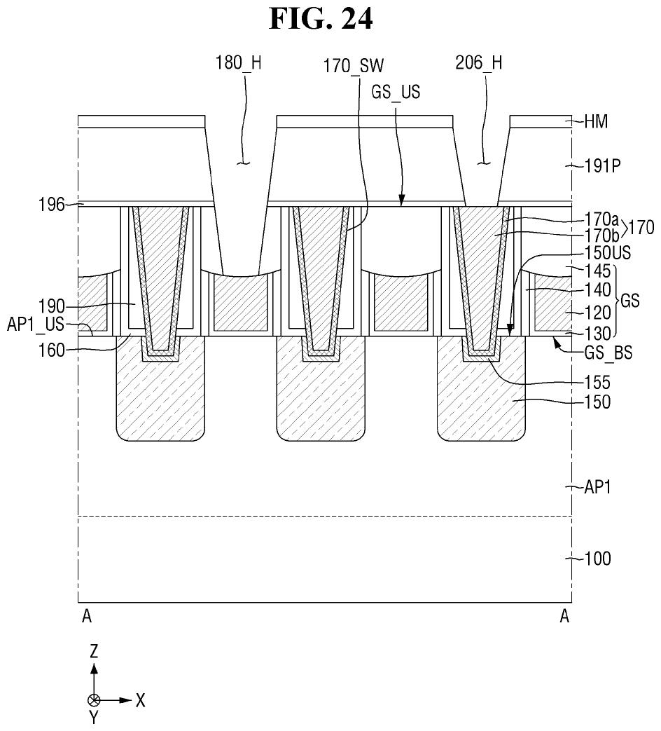

Referring to FIG. 24, a gate contact hole 180_H is formed on the gate structure GS, and a via hole 206_H is formed on the first source/drain contact 170.

Specifically, a first etching stop film 196 and a second pre-interlayer insulating film 191P may be formed on the gate structure GS and the first source/drain contact 170. Subsequently, a hole mask pattern HM may be formed on the second pre-interlayer insulating film 191P. The hole mask pattern HM may be formed by the same method as the method of forming the mask buffer pattern (170_M of FIG. 20) described above.

The gate contact hole 180_H and the via hole 206_H may be formed to penetrate the second pre-interlayer insulating film 191P and the hole mask pattern HM. The gate contact hole 180_H and the via hole 206_H may be formed by partially removing the second pre-interlayer insulating film 191P. The gate contact hole 180_H and the via hole 206_H may be formed at the same time.

The gate contact hole 180_H may expose the gate electrode 120. For example, the gate contact hole 180_H may penetrate the second pre-interlayer insulating film 191P and the gate capping film 145. A part of the first etching stop film 196 may be removed, while the gate contact hole 180_H and the via hole 206_H are being formed.

The via hole 206_H may expose first source/drain contact 170. For example, the via hole 206_H may penetrate the second pre-interlayer insulating film 191P.

The lower surface of the gate contact hole 180_H and the lower surface of the via hole 206_H may be placed at different heights. The height of the upper surface of the gate electrode 120 exposed by the gate contact hole 180_H may be different from the height of the upper surface of the first source/drain contact 170 exposed by the via hole 206_H. For example, the lower surface of the gate contact hole 180_H may be placed to be lower than the lower surface of the via hole 206_H on the basis of the upper surface AP1_US of the first active pattern.

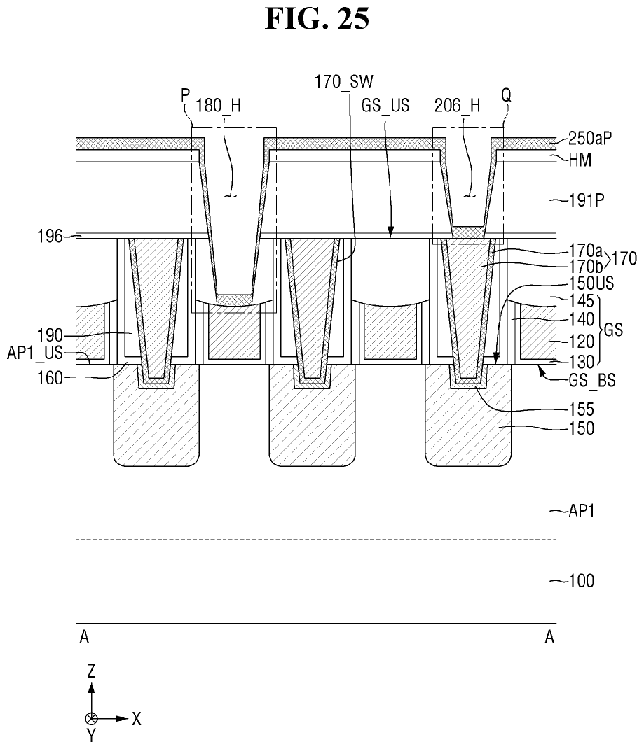

Referring to FIGS. 25 to 27, a pre-hole liner 250aP is formed in the gate contact hole 180_H and the via hole 206_H.

Specifically, the pre-hole liner 250aP may extend along the upper surface of the hole mask pattern HM, the gate contact hole 180_H and the via hole 206_H. The pre-hole liner 250aP may be formed simultaneously on the upper surface and in the gate contact hole 180_H and the via hole 206_H. The pre-hole liner 250aP may be formed using, for example, a physical vapor deposition (PVD) method. The pre-hole liner 250aP may include or be formed of tungsten (W) of single grain.

The pre-hole liner 250aP may include a first pre-bottom portion 180a1P and a first pre-side wall portion 180a2P, inside the gate contact hole 180_H. The first pre-bottom portion 180a1P may be formed on the bottom surface of the gate contact hole 180_H. The first pre-side wall portion 180a2P may extend along the inner side wall of the gate contact hole 180_H.

A first pre-thickness THIP of the first pre-bottom portion 180a1P may be greater than a second pre-thickness TH2P of the first pre-side wall portion 180a2P. The upper surface 180a1P_US of the first pre-bottom portion may be flat. However, the embodiments are not limited thereto. For example, the upper surface 180a1P_US of the first pre-bottom portion may have a convex shape toward the gate electrode 120. As another example, the upper surface 180a1P_US of the first pre-bottom portion may have a concave shape with respect to the gate electrode 120.

The second pre-thickness TH2P of the first pre-side wall portion 180a2P may not be constant. For example, the second pre-thickness TH2P may increase as it goes away from the first pre-bottom portion 180a1P. For example, the thickness of the first pre-side wall portion 180a2P may increase as it goes upward inside the gate contact hole 180_H.

The pre-hole liner 250aP may include a second pre-bottom portion 206a1P and a second pre-side wall portion 206a2P inside the via hole 206_H. The second pre-bottom portion 206a1P may be formed on the bottom surface of the via hole 206_H. The second pre-side wall portion 206a2P may extend along the inner side wall of the via hole 206_H.

A third pre-thickness TH3P of the second pre-bottom portion 206a1P may be greater than a fourth pre-thickness TH4P of the second pre-side wall portion 206a2P. An upper surface 206a1P_US of the second pre-bottom portion may be flat. However, embodiments are not limited thereto. For example, the upper surface 206a1P_US of the second pre-bottom portion may have a convex shape toward the first source/drain contact 170. As another example, the upper surface 206a1P_US of the second pre-bottom portion may have a concave shape with respect to the first source/drain contact 170.

The fourth pre-thickness TH4P of the second pre-side wall portion 206a2P may not be constant. For example, the fourth pre-thickness TH4P may increase away from the second pre-bottom portion 206a1P. For example, the second pre-side wall portion 206a2P may become thicker as it goes upward inside the via hole 206_H.

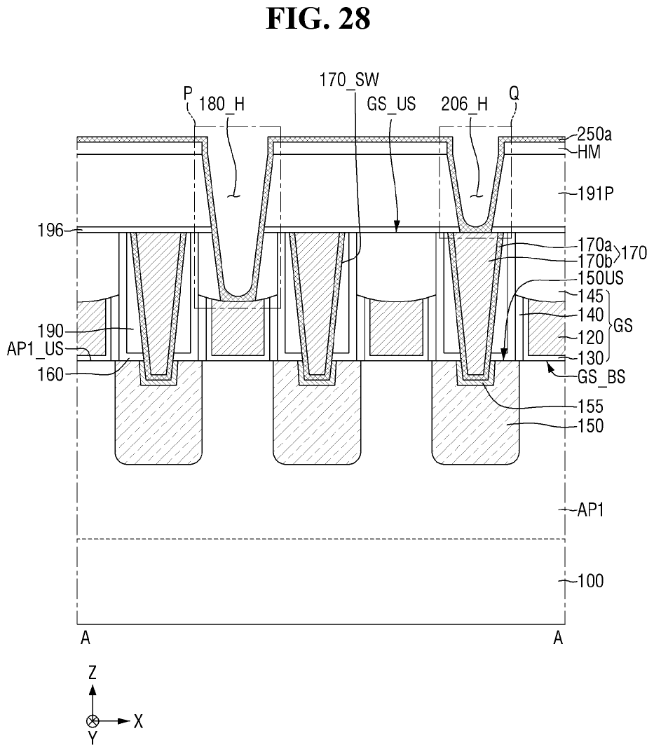

Referring to FIGS. 28 to 30, a hole liner 250a is formed.

Specifically, the pre-hole liner (250aP of FIGS. 25 to 27) may be etched to form the hole liner 250a.

The hole liner 250a may include a first bottom portion 180a1 and a first side wall portion 180a2 inside the gate contact hole 180_H. The hole liner 250a may include a second bottom portion 206a1 and a second side wall portion 206a2 inside the via hole 206_H.

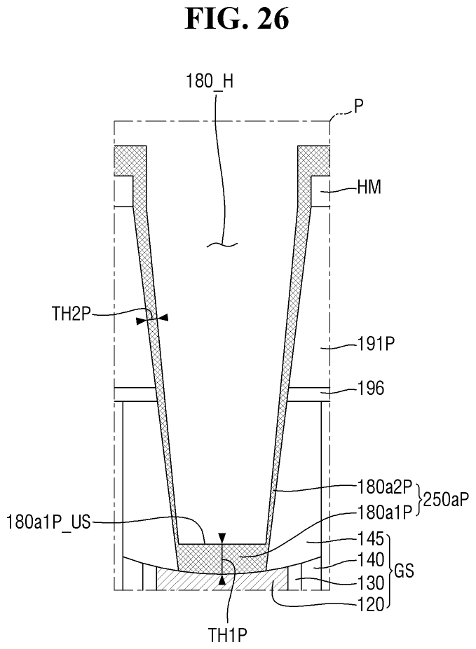

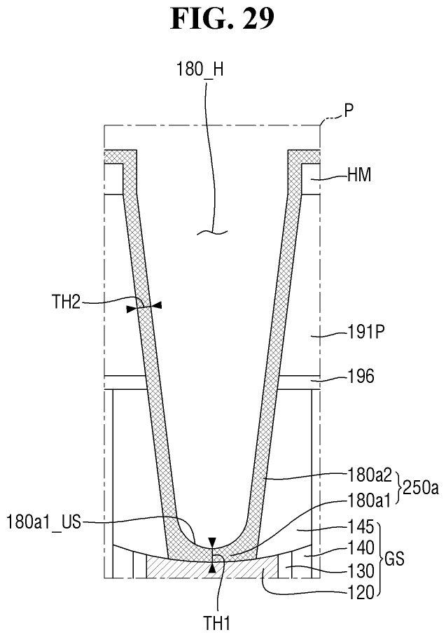

Referring to FIGS. 26 and 29, a part of the first pre-bottom portion 180a1P may be etched inside the gate contact hole 180_H. A first bottom portion 180a1 may be formed, by etching a part of the first pre-bottom portion 180a1P. The upper surface 180a1_US of the first bottom portion may have a convex shape toward the gate electrode 120, by etching a part of the first pre-bottom portion 180a1P. The first thickness TH1 of the first bottom portion 180a1 may be smaller than the first pre-thickness THIP of the first pre-bottom portion 180a1P.

A part of the etched first pre-bottom portion 180a1P may be sputtered to the first pre-side wall portion 180a2P. A part sputtered from the first pre-bottom portion 180a1P may be redeposited onto the first pre-side wall portion 180a2P to form the first side wall portion 180a2.

While a part sputtered from the first pre-bottom portion 180a1P is redeposited onto the first pre-side wall portion 180a2P, the lower thickness of the first side wall portion 180a2 may be made greater than the lower thickness of the first pre-side wall portion 180a2P. Accordingly, the second thickness TH2 of the first side wall portion 180a2 may be made constant. However, the embodiment is not limited thereto.

For example, the second thickness TH2 of the first side wall portion 180a2 is not constant, and may increase as it goes away from the first bottom portion 180a1, similarly to the first pre-side wall portion 180a2P. However, a difference between the second thickness TH2 of the first side wall portion 180a2 and the second pre-thickness TH2P of the first pre-side wall portion 180a2P may increase toward the first bottom portion 180a1. This may be attributed to the fact that an amount, which is etched at the first pre-bottom portion 180a1P, sputtered to the first pre-side wall portion 180a2P and redeposited, increases toward the first bottom portion 180a1.

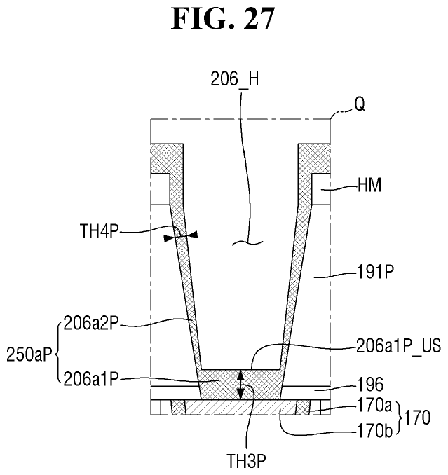

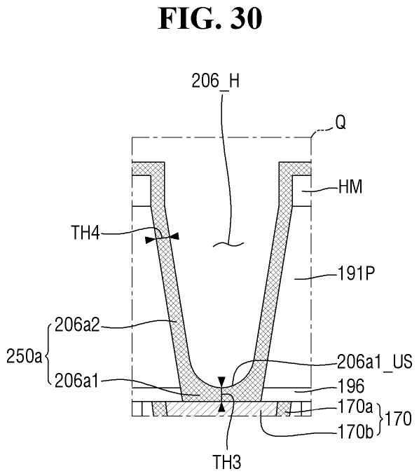

Referring to FIGS. 27 and 30, a part of the second pre-bottom portion 206a1P may be etched inside the via hole 206_H. A part of the second pre-bottom portion 206a1P may be etched to form the second bottom portion 206a1. While a part of the second pre-bottom portion 206a1P is etched, the upper surface 206a1_US of the second bottom portion may have a convex shape toward the first source/drain contact 170. The third thickness TH3 of the second bottom portion 206a1 may be smaller than the third pre-thickness TH3P of the second pre-bottom portion 206a1P.

A part of the etched second pre-bottom portion 206a1P may be sputtered to the second pre-side wall portion 206a2P. A part sputtered from the second pre-bottom portion 206a1P may be redeposited on the second pre-side wall portion 206a2P to form the second side wall portion 206a2.

While a part sputtered from the second pre-bottom portion 206a1P is redeposited onto the second pre-side wall portion 206a2P, the lower thickness of the second side wall portion 206a2 may be made greater than the lower thickness of the second pre-side wall portion 206a2P. Accordingly, the fourth thickness TH4 of the second side wall portion 206a2 may be made constant. However, the embodiment is not limited thereto.

For example, the fourth thickness TH4 of the second side wall portion 206a2 is not constant, and may increase away from the second bottom portion 206a1, similarly to the second pre-side wall portion 206a2P. However, a difference between the fourth thickness TH4 of the second side wall portion 206a2 and the fourth pre-thickness TH4P of the second pre-side wall portion 206a2P may increase, toward the second bottom portion 206a1. This may be attributed to the fact that an amount, which is etched at the second pre-bottom portion 206a1P, sputtered to the second pre-side wall portion 206a2P, and redeposited, increases toward the second bottom portion 206a1.

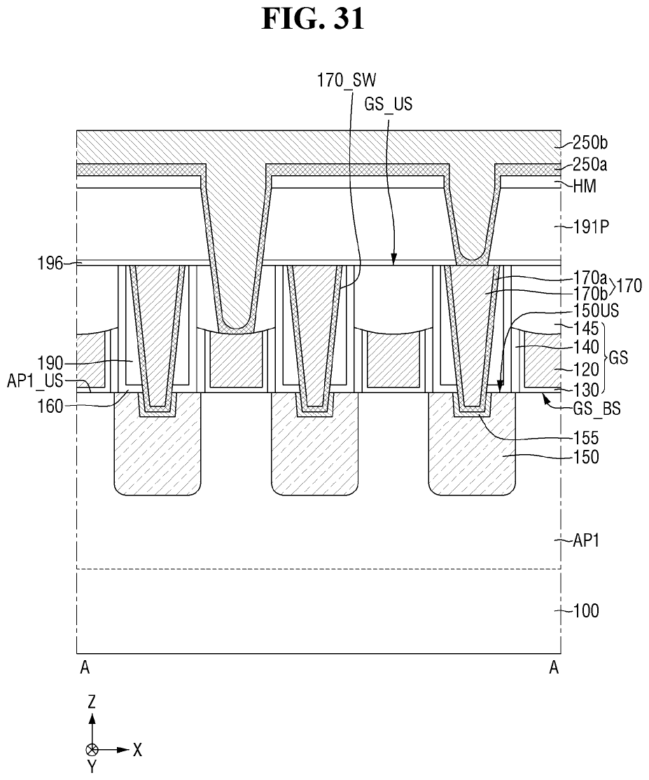

Referring to FIG. 31, a hole filling film 250b is formed.

The hole filling film 250b may be formed on the hole liner 250a. The hole filling film 250b may fill the gate contact hole (180_H of FIG. 28) and the via hole (206_H of FIG. 28) on the hole liner 250a. The hole filling film 250b may be formed using, for example, a chemical vapor deposition (CVD) method. The hole filling film 250b may include or be formed of tungsten (W) of single grain.

Subsequently, referring to FIG. 2, a gate contact 180 and a via plug 206 are formed, by removing the hole mask pattern HM, a part of the hole liner 250a and the hole filling film 250b, and a part of the second pre-interlayer insulating film 191P. For example, the hole liner 250a, the hole filling film 250b, and the second pre-interlayer insulating film 191P may be chemically mechanically polished. Accordingly, the upper surface of the gate contact 180 and the upper surface of the via plug 206 may be placed on the same plane.

Subsequently, a second etching stop film 197, a third interlayer insulating film 192 and a wiring line 207 are formed on the gate contact 180 and the via plug 206.

In concluding the detailed description, those skilled in the art will appreciate that many variations and modifications may be made to the preferred embodiments without departing from the scope of the present invention as defined by the appended claims. Therefore, the disclosed preferred embodiments of the invention are used in a generic and descriptive sense only and not for purposes of limitation.

1. A semiconductor device comprising:
an active pattern extending in a first direction;
a gate structure which is placed on the active pattern to be spaced apart from each other in the first direction, and includes a gate electrode and a gate spacer, the gate electrode extending in a second direction intersecting the first direction;
a gate contact on the gate structure;
a source/drain pattern on the active pattern;
a source/drain contact on the source/drain pattern; and
a via plug on the source/drain contact,
wherein an upper surface of the gate contact and an upper surface of the via plug are placed on the same plane, and
wherein a lower surface of the gate contact and a lower surface of the via plug are different in height, on the basis of an upper surface of the active pattern.

2. The semiconductor device of claim 1, wherein the gate contact includes a single grain.

3. The semiconductor device of claim 1, wherein each of the via plug and the gate contact includes tungsten (W).

4. The semiconductor device of claim 1, wherein the gate contact does not include titanium (Ti).

5. The semiconductor device of claim 1, wherein the gate contact does not include Si—H bonds.

6. The semiconductor device of claim 1, wherein the gate contact does not include boron (B).

7. The semiconductor device of claim 1, further comprising:
a contact silicide film between the source/drain pattern and the source/drain contact.

8. The semiconductor device of claim 1, wherein the gate contact includes:
a contact liner, and
a contact filling film on the contact liner, and
wherein the contact liner and the contact filling film include the same material.

9. The semiconductor device of claim 8, wherein a lower surface of the contact filling film has a convex shape toward the gate electrode.

10. The semiconductor device of claim 8, wherein the contact liner includes:
a bottom portion that surrounds the lower surface of the contact filling film, and
a side wall portion extending along a side surface of the contact filling film, and
wherein a thickness of the bottom portion is greater than a thickness of the side wall portion.

11. The semiconductor device of claim 1, wherein the via plug includes:
a via liner, and
a via filling film on the via liner, and
wherein the via liner and the via filling film include tungsten.

12. The semiconductor device of claim 11, wherein a lower surface of the via filling film has a convex shape toward the source/drain contact.

13. A semiconductor device comprising:
an active pattern extending in a first direction;
a gate structure which is placed on the active pattern to be spaced apart from each other in the first direction, and includes a gate electrode and a gate spacer, the gate electrode extending in a second direction perpendicular to the first direction;
a gate contact on the gate structure;
a source/drain pattern on the active pattern;
a source/drain contact on the source/drain pattern; and
a via plug on the source/drain contact,
wherein each of the gate contact and the via plug does not include titanium, and includes tungsten of a single grain.

14. The semiconductor device of claim 13, wherein the gate contact includes a contact liner, and a contact filling film on the contact liner,
wherein the via plug includes a via liner, and a via filling film on the via liner, and
wherein the contact liner, the contact filling film, the via liner and the via filling film include tungsten.

15. The semiconductor device of claim 14, wherein the contact liner includes:
a bottom portion that surrounds a lower surface of the contact filling film, and
a side wall portion extending along a side surface of the contact filling film, and
wherein an upper surface of the bottom portion has a convex shape toward the gate electrode.

16. The semiconductor device of claim 14, wherein the via liner includes:
a bottom portion which surrounds a lower surface of the via filling film, and
a side wall portion extending along a side surface of the via filling film, and
wherein an upper surface of the bottom portion has a convex shape toward the source/drain contact.

17. The semiconductor device of claim 13, wherein an upper surface of the gate contact and an upper surface of the via plug are placed on the same plane.

18. The semiconductor device of claim 13, wherein the active pattern includes:
a lower pattern which extends in the first direction, and
a plurality of sheet patterns which are spaced apart from the lower pattern in a third direction perpendicular to the first direction and the second direction.

19. A semiconductor device comprising:
an active pattern extending in a first direction;
a gate structure which is placed on the active pattern to be spaced apart in the first direction, and includes a gate electrode and a gate spacer, the gate electrode extending in a second direction intersecting the first direction;
a gate contact on the gate structure;
a source/drain pattern on the active pattern;
a source/drain contact on the source/drain pattern;
a via plug on the source/drain contact; and
a wiring line which is in contact with the gate contact and the via plug, wherein:
an upper surface of the gate contact and an upper surface of the via plug are placed on the same plane,
the gate contact and the via plug each includes tungsten of single grain,
the gate contact includes a contact liner, and a contact filling film on the contact liner, and
a lower surface of the contact filling film has a convex shape toward the gate electrode.

20. The semiconductor device of claim 19, further comprising:
an etching stop film which covers the upper surface of the source/drain contact, on the source/drain contact and the gate structure; and
an interlayer insulating film placed below the wiring line on the etching stop film,
wherein the gate contact penetrates the etching stop film and the interlayer insulating film.

21. (canceled)
